(19) United States
(12) Patent Application Publication
(10) Pub. No.: US 2016/0349634 A1
(43) Pub. Date: Dec. 1, 2016

(54) MOLD, METHOD AND APPARATUS OF IMPRINTING, AND METHOD FOR PRODUCING PRODUCT

(71) Applicant: CANON KABUSHIKI KAISHA, Tokyo (JP)

(72) Inventors: Yusuke Tanaka, Tokyo (JP); Eiji Sakamoto, Utsunomiya-shi (JP); Noriyasu Hasegawa, Utsunomiya-shi (JP)

(21) Appl. No.: 15/161,884

(22) Filed: May 23, 2016

(30) Foreign Application Priority Data
May 29, 2015 (JP) 2015-109430

(51) Int. Cl. G03F 9/00; B29C 59/02; G03F 7/00

(52) U.S. Cl. CPC G03F 9/7042; G03F 7/0002; B29C 59/022; B29C 2059/023

(57) ABSTRACT

A mold for use in an imprinting apparatus that forms patterns of an imprint material on a plurality of shot regions on a substrate includes a plurality of pattern regions for forming the patterns. The pattern regions are disposed so as not to be next to each other in a first direction and a second direction. The plurality of pattern regions each have a first peripheral region and a second peripheral region at both ends in the first direction. The first peripheral region and the second peripheral region are disposed such that, in forming the patterns in the plurality of shot regions along the first direction, a pattern of the imprint material formed in a shot region using the first peripheral region of the pattern region is superposed on a pattern of the imprint material formed in a next shot region using the second peripheral region.

### BACKGROUND OF THE INVENTION

### Field of the Invention

The present invention relates to a mold for use in imprinting, a method and an apparatus of imprinting for forming a pattern using the mold, and a method for producing a product.

### Description of the Related Art

Known techniques for producing semiconductor devices and micro-electro-mechanical systems (MEMS) include an imprinting technique for forming patterns on a resin on a substrate using a mold, in addition to conventional photolithography.

Imprint regions of substrates on which patterns are formed using the imprinting technique are sometimes deformed. For example, heating the substrate during deposition, such as sputtering, before the step of patterning using imprinting will increase or reduce the size of the substrate. Therefore, the imprinting apparatus aligns the shape of the imprint region (an underlying pattern) formed in advance on the substrate with the shape of a pattern region formed on the mold. A known technique for aligning the shape of the substrate-side imprint region with the mold-side pattern region is a method for aligning the shapes by deforming the mold with force.

Another known method of imprinting disclosed in Japanese Patent Laid-Open No. 2012-204722 forms patterns on a plurality of imprint regions in a single imprinting process using a mold on which patterns corresponding to the plurality of imprint regions on the substrate are formed. In this case, a plurality of patterns are formed by a single imprinting operation while the plurality of pattern regions of the mold are deformed to the plurality of imprint regions on the substrate. Japanese Patent Laid-Open No. 2012-204722 discloses a mold for forming patterns on a plurality discontinuous (non-adjacent) imprint regions on a substrate.

In forming patterns on a plurality of imprint regions by repeating an imprinting operation, the patterns have to be formed such that no gap is present between the resins of the imprint regions. Furthermore, the patterns have to be formed such that the resin is uniform in thickness across the plurality of imprint regions. For this purpose, Japanese Patent Laid-Open No. 2014-175620 discloses a method of forming a thin resin region around the periphery of each patterns formed on a substrate (a portion in contact with an adjacent imprint region) and forming a pattern in the adjacent imprint region such that the pattern overlaps with the thin resin region.

However, with the method of forming patterns in a plurality of adjacent imprint regions by repeating the imprinting operation using a mold having a plurality of non-continuous pattern regions, as disclosed in Japanese Patent Laid-Open No. 2012-204722, such imprinting that the patterns overlap with thin resin regions cannot be performed. This can cause gaps between the resins of the imprint regions.

### SUMMARY OF THE INVENTION

The present invention provides a mold for use in an imprinting apparatus that forms patterns of an imprint material on a plurality of shot regions on a substrate includes a plurality of pattern regions for forming the patterns. The pattern regions are disposed so as not to be next to each other in a first direction and a second direction. The plurality of pattern regions each have a first peripheral region and a second peripheral region at both ends in the first direction. The first peripheral region and the second peripheral region are disposed such that, in forming the patterns in the plurality of shot regions along the first direction, a pattern of the imprint material formed in a shot region using the first peripheral region of the pattern region is superposed on a pattern of the imprint material formed in a next shot region using the second peripheral region.

Further features of the present invention will become apparent from the following description of exemplary embodiments with reference to the attached drawings.

### BRIEF DESCRIPTION OF THE DRAWINGS

FIG. 1 is a diagram illustrating, in outline, the configuration of an imprinting apparatus according to an embodiment of the present invention.

FIG. 2 is a flowchart showing an operating sequence of the imprinting apparatus according to the embodiment.

FIG. 3A is a diagram illustrating problems in imprinting operation of related art.

FIG. 3B is a diagram illustrating problems in imprinting operation of related art.

FIG. 4 is a diagram illustrating problems in imprinting operation of related art.

FIG. 5A is a diagram illustrating a mold according to a first embodiment of the present invention.

FIG. 5B is a diagram illustrating a mold according to the first embodiment of the present invention.

FIG. 6A is a diagram illustrating a mold according to a second embodiment of the present invention.

FIG. 6B is a diagram illustrating the sequence of forming patterns using the mold shown in FIG. 6A.

FIG. 7 is a diagram illustrating a mold according to a third embodiment of the present invention.

FIG. 8A is a diagram illustrating a mold according to a fourth embodiment of the present invention.

FIG. 8B is a diagram illustrating the sequence of forming patterns using the mold shown in FIG. 8A.

### DESCRIPTION OF THE EMBODIMENTS

Embodiments of the present invention will be described hereinbelow with reference to the accompanying drawings. In the drawings, like components are given like reference signs, and duplicate descriptions will be omitted.

### First Embodiment

### Imprinting Apparatus

First, a mold for imprinting and an imprinting apparatus that forms patterns of an imprint material on a substrate using the mold for imprinting according to a first embodiment of the present invention will be described.

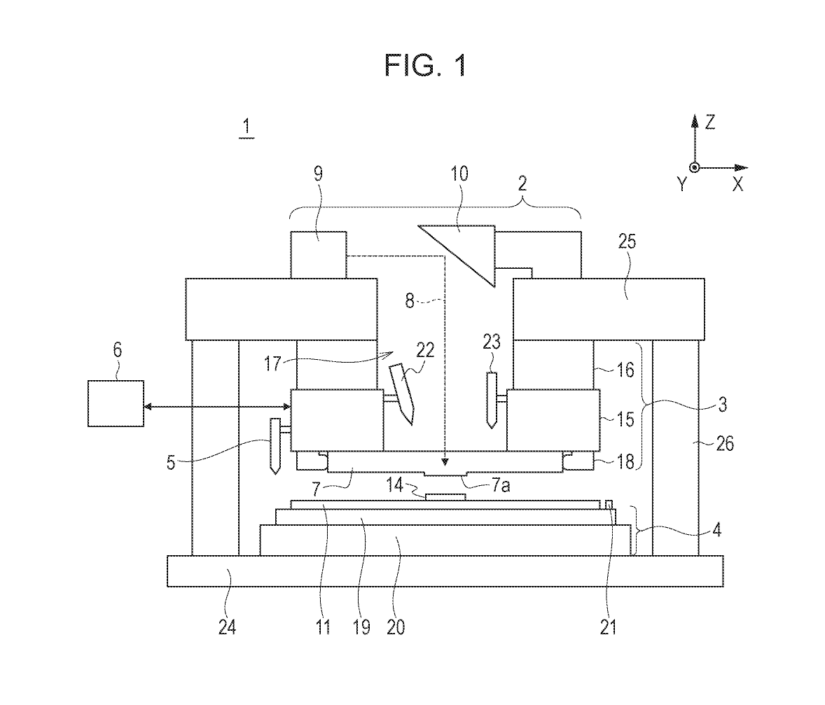

FIG. 1 is a diagram illustrating the configuration of an imprinting apparatus 1. The imprinting apparatus 1 according to the first embodiment is an apparatus for use in producing devices, or products, such as a semiconductor device. The imprinting apparatus 1 is configured to mold an uncured resin (an imprint material) on a wafer (a substrate), or a workpiece, with a mold to form a pattern of the imprint material. In this embodiment, the imprinting apparatus 1 adopts a photo-curing method. In the following drawings, the Z-axis is a direction in which light (for example, ultraviolet light) is applied to an imprint material 14 on a substrate 11, and the X-axis and the Y-axis that cross at right angles are set in a plane perpendicular to the Z-axis. The imprinting apparatus 1 includes a light irradiation unit 2, a mold holding mechanism 3, a substrate stage 4, a coating unit 5, and a control unit 6.

The light irradiation unit 2 emits ultraviolet light 8 to the imprint material 14 through the mold 7, with the imprint material 14 on the substrate 11 and the mold 7 in contact. The light irradiation unit 2 includes a light source 9 and an optical element 10 for adjusting the ultraviolet light 8 emitted from the light source 9. The first embodiment includes the light irradiation unit 2 because it adopts the photo-curing method, whereas, if a thermosetting method is adopted, a heat source for curing a thermosetting resin is used in place of the light irradiation unit 2.

The mold 7 is rectangular in outer shape and includes a pattern region 7a (a pattern portion) having a three-dimensional pattern (for example, a relief pattern, such as a circuit pattern, to be transferred onto the substrate 11) on a surface facing the substrate 11. The pattern region 7a is rectangular in shape and is enclosed by a peripheral region. The mold 7 is made of a material, such as quartz, through which the ultraviolet light 8 can pass.

The mold holding mechanism 3 (a mold holding unit) includes a mold chuck 15 that holds the mold 7 by vacuum attraction or electrostatic force and a mold driving mechanism 16 that holds and moves the mold chuck 15. The mold chuck 15 and the mold driving mechanism 16 have an opening region 17 in the center so that the ultraviolet light 8 emitted from the light source 9 of the light irradiation unit 2 travels toward the imprint material 14 on the substrate 11. The mold holding mechanism 3 further includes a correction mechanism 18 (a deforming mechanism) that changes the shape of the mold 7 (a plurality of pattern regions 7a) by applying force to the side of the mold 7. The correction mechanism 18 can shape the pattern regions 7a formed on the mold 7 to the shape of shot regions formed in advance on the substrate 11 by changing the shape of the mold 7. For example, the correction mechanism 18 can make the magnification of the pattern regions 7a equal to the magnification of the shot regions.

The mold driving mechanism 16 moves the mold 7 in the Z-axis direction so as to selectively bring the mold 7 into contact (imprint) and out of contact (release) with the imprint material 14 on the substrate 11. Examples of an actuator adoptable to the mold driving mechanism 16 include a linear motor and an air cylinder. To address high-accuracy positioning of the mold 7, the mold driving mechanism 16 may be constituted by a plurality of driving systems including a coarse-adjustment driving system and a fine-adjustment driving system. The mold driving mechanism 16 may further include a position adjusting mechanism not only for the Z-axis direction but also for the X-axis direction, the Y-axis direction, and the θ (rotation about the Z-axis) direction and a tilting function for correcting the tilt of the mold 7. While the imprinting and releasing operations of the imprinting apparatus 1 may be performed by moving the mold 7 in the Z-axis direction, as described above, the operations may be achieved by moving the substrate stage 4 in the Z-axis direction or by moving both of the mold 7 and the substrate stage 4 relative to each other.

Examples of the substrate 11 include a monocrystal silicon substrate, a silicon-on-insulator (SOI) substrate, and a glass substrate. The surface of the substrate 11 to be processed is supplied with the imprint material 14 to be molded using the pattern regions 7a of the mold 7.

The substrate stage 4 (a substrate holder) aligns the mold 7 and the substrate 11 when the mold 7 and the imprint material 14 on the substrate 11 are brought into contact with each other. The substrate stage 4 includes a substrate chuck 19 that holds the substrate 11 by vacuum attraction or electrostatic force and a substrate driving mechanism 20 that mechanically holds the substrate chuck 19 and moves the substrate 11 in an X-Y plane. The substrate chuck 19 has a reference mark 21 for use in aligning the mold 7. An example of an actuator adaptable to the substrate driving mechanism 20 is a linear motor. The substrate driving mechanism 20 may also constituted by a plurality of driving systems including a coarse adjustment system and a fine adjustment system for the X-axis and Y-axis directions. The substrate driving mechanism 20 may further include a driving system for adjusting the position in the Z-axis direction, a position adjusting mechanism for the substrate 11 in the θ direction, and a tilting function for correcting the tilt of the substrate 11.

The coating unit 5 (a dispenser) is used to apply (supply) the uncured imprint material 14 onto the substrate 11. The imprint material 14 is a photocurable resin having the property of setting when irradiated with the ultraviolet light 8 and is selected as appropriate according to conditions for the semiconductor device production process. The coating unit 5 has a plurality of ejection ports (ejection nozzles) on a surface facing the substrate 11. The amount of the imprint material 14 ejected from the ejection ports is determined as appropriate according to the thickness of the imprint material 14 to be formed on the substrate 11, the density of the patterns formed, and so on.

The control unit 6 includes a memory in which programs for controlling the operation of the imprinting apparatus 1 are stored and a processor that implements the programs stored in the memory. The control unit 6 outputs signals for controlling the individual units constituting the imprinting apparatus 1 according to the implemented programs. The control unit 6 further controls the amount of deformation of the pattern regions 7a of the mold 7 with the correction mechanism 18 when patterns are to be formed with the imprinting apparatus 1. An example of the control unit 6 is a computer, which is connected to the individual components of the imprinting apparatus 1 to control the components according to the programs. The control unit 6 of this embodiment controls at least the operation of the mold holding mechanism 3 (the mold chuck 15). The control unit 6 may be integrated with the imprinting apparatus 1 (in a common casing) or may be separate from the imprinting apparatus 1 (in a different casing).

The imprinting apparatus 1 further includes an alignment detection system 22 that detects alignment marks. The imprinting apparatus 1 may further include a distance measurement system 23 that measures the distance between the mold 7 and the substrate 11.

The alignment detection system 22 detects an alignment mark at the substrate 11 and an alignment mark at the mold 7. The imprinting apparatus 1 aligns the mold 7 and the substrate 11 using the result of detection of the alignment marks that the alignment detection system 22 detects. Specifically, the imprinting apparatus 1 obtains the displacement of the alignment mark at the mold 7 and the alignment mark at the substrate 11 in the X-axis and the Y-axis from the result of detection of the alignment marks using the alignment detection system 22.

The distance measurement system 23 measures the distance by observing interference light with an image sensor. The interference light is light in which light emitted from a light source for measurement is reflected by and transmitted through the substrate 11 and the mold 7 to interfere with one another.

The imprinting apparatus 1 further includes a base platen 24 on which the substrate stage 4 is placed, a bridge platen 25 that fixes the mold holding mechanism 3, and a support column 26 disposed on the base platen 24, for supporting the bridge platen 25. The imprinting apparatus 1 further includes a mold conveying mechanism (not shown) that conveys the mold 7 to the mold holding mechanism 3 and a substrate conveying mechanism (not shown) that conveys the substrate 11 to the substrate stage 4.

### Imprinting Operation

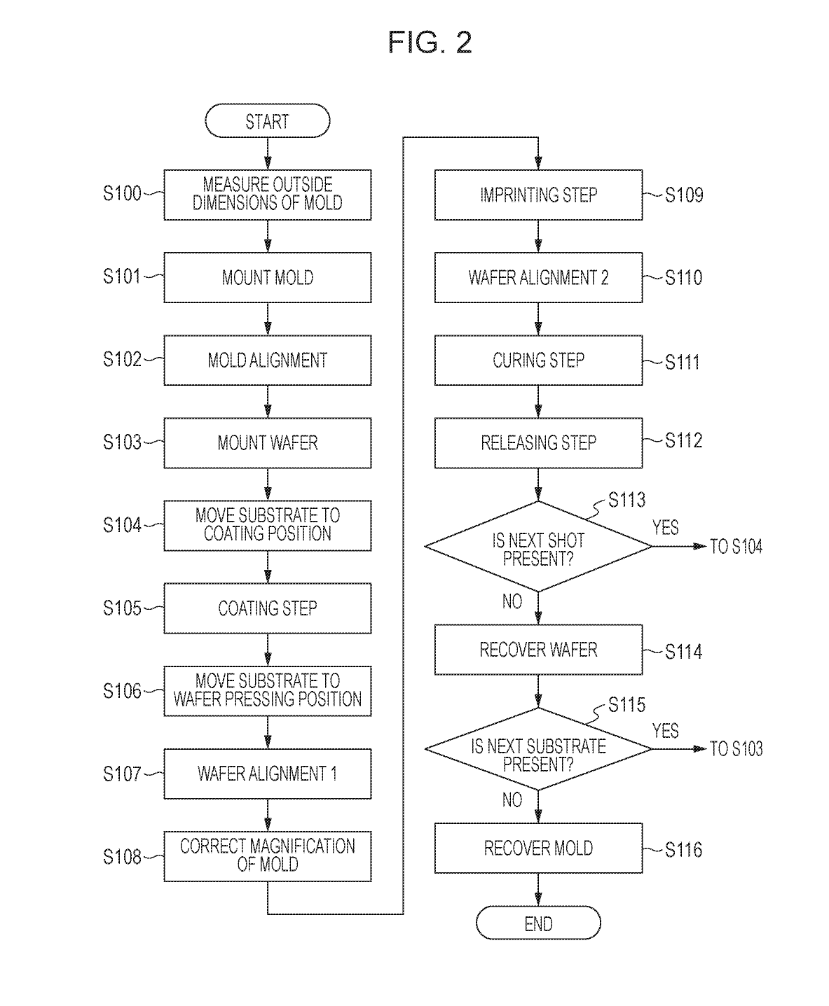

The operation of the imprinting apparatus 1 will be described with reference to FIG. 2. FIG. 2 is a flowchart showing an operating sequence for forming patterns of the imprint material 14 on a plurality of substrates 11 using the imprinting apparatus 1. The substrate 11 has a plurality of shot regions. By repeating an imprinting process from one shot region to another, patterns can be formed on the substrates 11. In the first embodiment, the patterns are formed in a single lot including a plurality of substrates 11 using the same mold 7.

Before the mold 7 is mounted to the mold holding mechanism 3, the outer shape of the mold 7 is measured in advance using a three-dimensional measuring machine or the like (S100).

The mold 7 is conveyed to the mold chuck 15 using the mold conveying mechanism to thereby mount the mold 7 to the mold holding mechanism 3 (S101).

Next, the control unit 6 controls the alignment detection system 22 to detect the reference mark 21 and the alignment mark at the mold 7, thereby detecting deviations in the X-axis, Y-axis, and θ (Z-axis) directions. At that time, the control unit 6 causes the mold driving mechanism 16 and/or the substrate driving mechanism 20 to perform mold alignment in which the reference mark 21 and the alignment mark at the mold 7 are aligned on the basis of the detection result (S102).

Next, the control unit 6 controls the substrate conveying mechanism to convey the substrate 11 onto the substrate chuck 19 (S103).

Next, the control unit 6 controls the substrate driving mechanism 20 to move the substrate 11 so that the shot region (the imprint region) on the substrate 11 is positioned at the application position of the coating unit 5 (S104).

Next, the control unit 6 controls the coating unit 5 to apply (supply) the imprint material 14 to the shot region on the substrate 11 (S105: coating step). At that time, the control unit 6 controls the amount and the position of the imprint material 14 applied so that the imprint material 14 has a desired thickness.

Next, the control unit 6 controls the substrate driving mechanism 20 to move the substrate 11 so that the shot region on the substrate 11 is positioned at a pressing position (imprinting position) directly under the pattern region 7a on the mold 7 (S106). When or after the substrate 11 is moved, the alignment detection system 22 detects the relative positions of the alignment mark at the substrate 11 and the alignment mark at the mold 7. The control unit 6 obtains an amount of driving of the correction mechanism 18 from the detection result (S107). Thereafter, the control unit 6 controls the correction mechanism 18 to be driven by the amount of driving obtained at step S107 to correct the shape of the mold 7 (S108).

The control unit 6 controls the mold driving mechanism 16 to bring the mold 7 (the pattern region 7a) close to the substrate 11, with the mold 7 deformed, into contact with the imprint material 14 on the substrate 11 (S108: imprinting step).

Although the correction of the shape of the mold 7 at step S108 in the operating sequence shown in FIG. 2 is performed before the imprinting step at step S109, the correction may be performed after or during the imprinting step at step S109.

The control unit 6 adjusts the position of the substrate driving mechanism 20 to minimize the displacement of the relative positions of the alignment mark at the substrate 11 and the alignment mark at the mold 7, which is generated at the imprinting step at step S109 (S110). The step S110 may be continuously performed during the processes from the step S106 to step S108.

Next, the control unit 6 controls the light irradiation unit 2 to emit the ultraviolet light 8 to the imprint material 14, with the mold 7 and the imprint material 14 in contact, to cure the imprint material 14 (S111: curing step).

Next, the control unit 6 controls the mold driving mechanism 16 to increase the distance between the mold 7 and the substrate 11, thereby releasing the mold 7 (the pattern region 7a) from the imprint material 14 on the substrate 11 (S112: releasing step).

Next, the control unit 6 determines whether a shot region on which a pattern is to be formed is present on the substrate 11 (S113). If the control unit 6 determines that a new shot region is present (YES at S113), then the control unit 6 goes to step S104, where the imprinting step from step S105 to step S112 is performed on the new shot region. In contrast, if it is determined that no new shot region is present (NO at S113), the control unit 6 controls the substrate conveying mechanism to recover (take out) the substrate 11 from the substrate chuck 19 (S114).

Next, the control unit 6 determines whether a substrate 11 to be processed next is present (S115). If the control unit 6 determines that a new substrate 11 is present (YES at S115), then the control unit 6 goes to step S103, where the imprinting step from step S104 to S114 is performed on the new substrate 11. In contrast, if the control unit 6 determines that no new substrate is present (NO at S115), then the control unit 6 controls the mold conveying mechanism to recover (take out) the mold 7 from the mold chuck 15 (S116) and terminate the operating sequence.

### Shape of Mold

Next, the order of the positions of shot regions when the imprinting process is repeated to form patterns on a plurality of shot regions on the substrate 11 will be described.

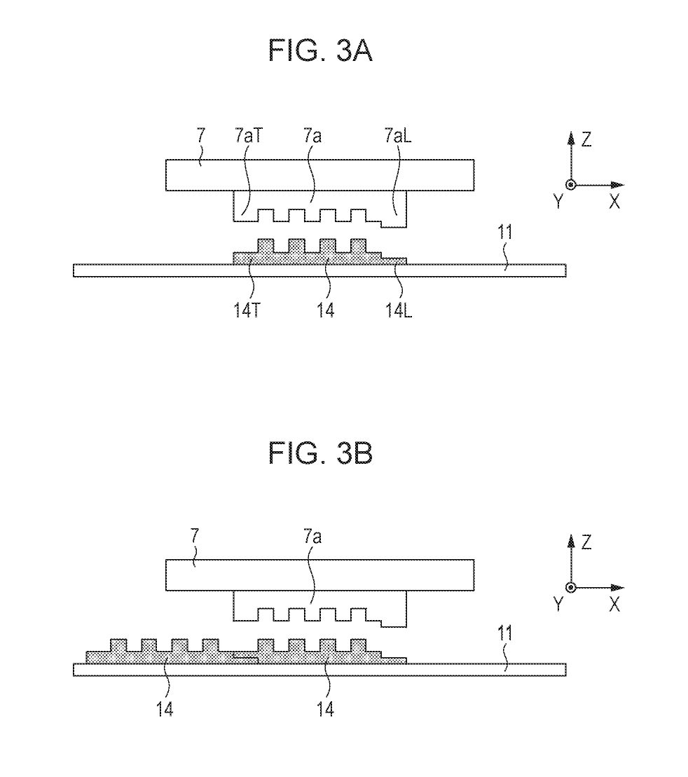

As illustrated in FIG. 3A, the periphery (the peripheral region) of the pattern region 7a formed on the mold 7 has two different edge shapes. An edge 7aL (a first peripheral region) protrudes in the direction facing the substrate 11 (−Z direction) more than an edge 7aT (a second peripheral region). The pattern region 7a is larger in thickness at the edge 7aL (the first peripheral region) than at the edge 7aT (the second peripheral region). For this reason, the distance between the mold 7 and the substrate 11 when the pattern region 7a of the mold 7 and the substrate 11 are opposed is smaller at the edge 7aL (the first peripheral region) than at the edge 7aT (the second peripheral region). Now, the edge 7aL (the first peripheral region) is defined as a leading edge 7aL, and the edge 7aT (the second peripheral region) is defined as a trailing edge 7aT. Thus, the mold 7 has the first peripheral region and the second peripheral region at both ends of the pattern region 7a. The first peripheral region and the second peripheral region have different structures.

When a pattern of the imprint material 14 is formed using the mold 7, a first peripheral region 14L in which the imprint material 14 has a small thickness and a second peripheral region 14T in which the imprint material 14 has a large thickness are formed around the periphery (the peripheral region) of the pattern region 7a. The first peripheral region 14L of the shot region is formed using the leading edge 7aL of the mold 7, and the second peripheral region 14T of the shot region is formed using the trailing edge 7aT.

Thus, portions of the pattern region 7a corresponding to regions of the imprint material 14 to be small in thickness protrude so that the distance between the substrate 11 and the mold 7 is small after imprinting. An edge of the pattern region 7a of the mold 7 corresponding to the region of the imprint material 14 to be thin is referred to as an leading edge, and an edge of the pattern region 7a for imprinting superposed on this region is referred to as a trailing edge.

A case where a pattern is formed in the shot region shown in FIG. 3A, and then a pattern is formed in a shot region next to the shot region in the +X direction on the substrate 11 will be described. As shown in FIG. 3B, a pattern is formed so that the trailing edge 7aT of the mold 7 is superposed on the first peripheral region 14L formed first. The second peripheral region 14T is formed on the first peripheral region 14L, which is formed first, using the trailing edge 7aT of the mold 7. In bringing the mold 7 into contact with the imprint material 14 on the substrate 11, the distance between the trailing edge 7aT of the mold 7 illustrated in FIGS. 3A and 3B and the surface of the substrate 11 is equal to the distance between the surface of the relief pattern (the surfaces of the protruding portions) of the pattern region 7a and the surface of the substrate 11. However, the trailing edge 7aT may be formed so that the distance between the trailing edge 7aT and the substrate 11 is larger than the distance between the surface of the pattern region 7a and the surface of the substrate 11.

By repeating such pattern formation, as shown in FIG. 3B, on shot regions adjacent in the +X direction, a film (a residual film) of an imprint material 14 with a uniform thickness can be formed without forming a gap between the shot regions. Furthermore, even if a little error occurs in the amount of the imprint material 14 applied to the first peripheral region 14L, so that the imprint material 14 runs off a desired region, formation of a gap can be reduced by performing imprinting, with the trailing edge 7aT superposed thereon. This method allows errors to be corrected by performing imprinting, with the next shot region superposed, even if the amount of the imprint material 14 applied varies a little to cause the imprint material 14 to run off a predetermined region.

In performing imprinting using a mold having a leading edge and a trailing edge, the sequence of imprinting is set appropriately so that the trailing edge is superposed on the imprint material formed around the leading edge. The edge (the peripheral region) of the mold 7 is also disposed appropriately.

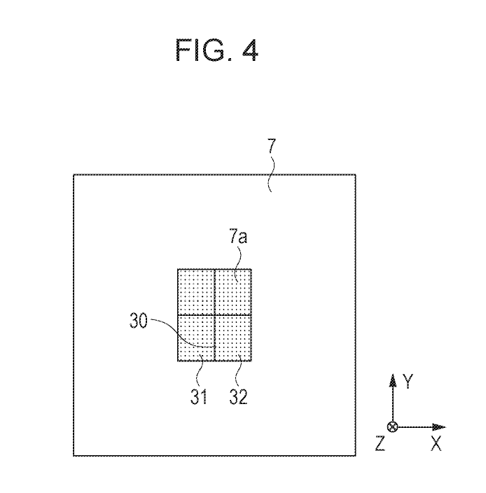

Next, a case where the mold 7 has a plurality of pattern regions 7a will be described. FIG. 4 is a diagram of a mold 7 in which four pattern regions 7a are disposed next to each other viewed from the -Z direction in FIG. 1. In the case where the pattern regions 7a are disposed next to each other, an edge 30 (a peripheral region) is shared by a pattern region 31 and a next pattern region 32 of the pattern region 7a. The shape of the edge 30 when only the pattern region 31 is corrected to an ideal shape and the shape of the edge 30 when only the pattern region 32 is corrected to an ideal shape differ. However, since the edge 30 is shared by the pattern region 31 and the pattern region 32, it is difficult to correct the shape of the pattern region 7a with the correction mechanism 18. Since the imprinting apparatus 1 performs the correction by physically deforming the mold 7, it is difficult to perform high-accuracy correction. For this reason, the plurality of pattern regions 7a of the mold 7 for use in the imprinting apparatus 1 are disposed so as not to be next to each other to enable correction of a non-continuous shape of the plurality of pattern regions 7a.

Thus, a mold that satisfies the following two conditions is used for forming a plurality of patterns (batch imprinting). A first condition is that the pattern regions 7a are disposed so as not to be next to each other on the mold 7. A second condition is that the mold 7 has a shape that allows imprinting such that the trailing edge 7aT is superposed on the first peripheral region 14L formed using the leading edge 7aL.

In forming patterns on the substrate 11 using such a mold 7, the pattern is to be formed in a shot region shifted stepwise by one shot region toward the leading edge 7aL from the shot region in which the pattern is formed. The direction of the stepwise movement is a direction along one side of the pattern region 7a and is defined as an imprinting step direction (a first direction). Upon completion of pattern formation in a plurality of shot regions disposed in the imprinting step direction, the operation is shifted to a position perpendicular to the imprinting step direction toward the leading edge 7aL, where imprinting is performed again in the imprinting step direction. The peripheral regions of the plurality of pattern regions 7a of the mold 7 may each have the leading edge 7aL and the trailing edge 7aT in a direction perpendicular to the imprinting step direction (a second direction). A combined vector of the imprinting step direction and a direction that is perpendicular to the imprinting step direction and is shifted stepwise by one shot region is defined as a forward direction, and a direction opposite to the forward direction is defined as a backward direction.

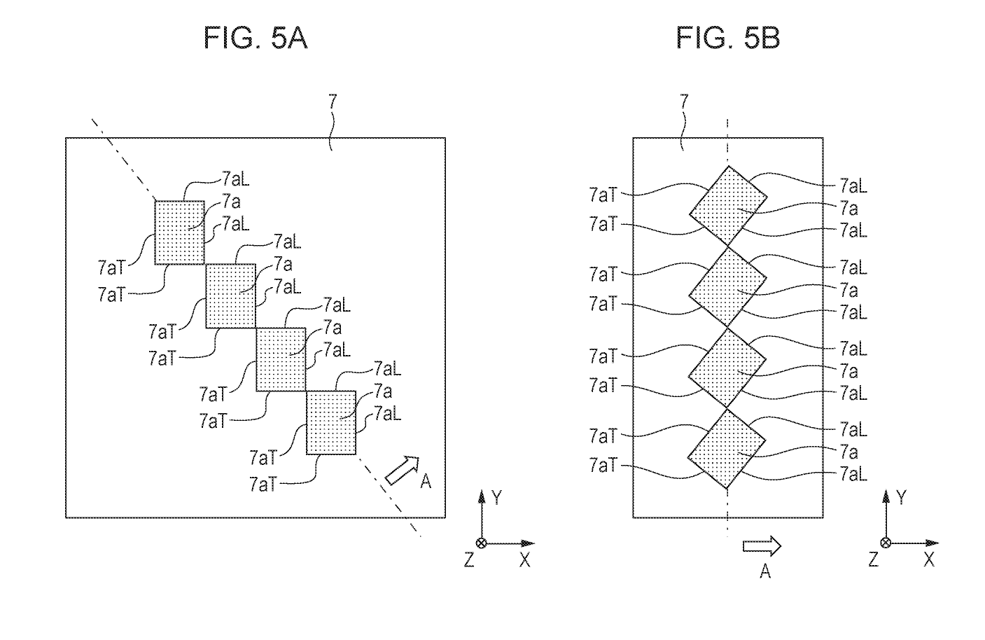

The mold 7 according to the first embodiment that satisfies the above conditions will be described hereinbelow. The mold 7 illustrated in FIGS. 5A and 5B has the pattern regions 7a disposed so that their apices are next to each other along the diagonal lines of the pattern regions 7a. The mold 7 according to the first embodiment will be described with reference to FIG. 5A. The mold 7 is held by the mold holding mechanism 3 of the imprinting apparatus 1 and is used for forming patterns. Although FIG. 5A illustrates four pattern regions 7a disposed along the diagonal lines, the number of pattern regions 7a is not limited to a particular number and may be, for example, only two. Among the pattern regions 7a, the peripheral regions (edges) positioned in the forward direction with respect to the one-dot chain line in FIG. 5A (in the direction of arrow A in FIG. 5A) each have the leading edge 7aL, and the peripheral regions positioned in the backward direction each have the trailing edge 7aT. Since the peripheral regions of the individual pattern regions 7a are not shared, high-accuracy shape correction can be performed even if the shapes of the pattern regions 7a are non-continuous. By performing imprinting while moving the mold 7 one shot region by one shot region in the +X direction in FIG. 5A, the trailing edge 7aT is imprinted on the first peripheral region 14L formed with the leading edge 7aL. In this way, a pattern is formed in the adjacent shot region so as to be superposed on an end of the pattern of the imprint material 14 formed in the shot region. This allows a film of the imprint material 14 with a uniform thickness to be formed without forming a gap between the shot regions. Thus, the mold 7 has the leading edge 7aL (the first peripheral region) and the trailing edge 7aT (the second peripheral region) having different shapes at both ends of each pattern region 7a.

However, disposing the pattern regions 7a along the diagonal lines can increase the size of the mold 7. In such a case, tilting the pattern regions 7a with respect to the mold 7, as illustrated in FIG. 5B, reduces the increase in the size of the mold 7. Among the pattern regions 7a, the peripheral regions positioned in the forward direction with respect to the one-dot chain line in FIG. 5B (in the direction of arrow A in FIG. 5A) each have the leading edge 7aL, and the edges positioned in the backward direction each have the trailing edge 7aT. In forming patterns on the substrate 11 using the mold 7 shown in FIG. 5B, at least one of the mold 7 and the substrate 11 is rotated about the Z-axis so that the pattern regions 7a of the mold 7 and the shot regions of the substrate 11 are superposed. Then, the mold 7 is moved stepwise by one shot region toward the leading edge 7aL of the mold 7 to form patterns.

### Second Embodiment

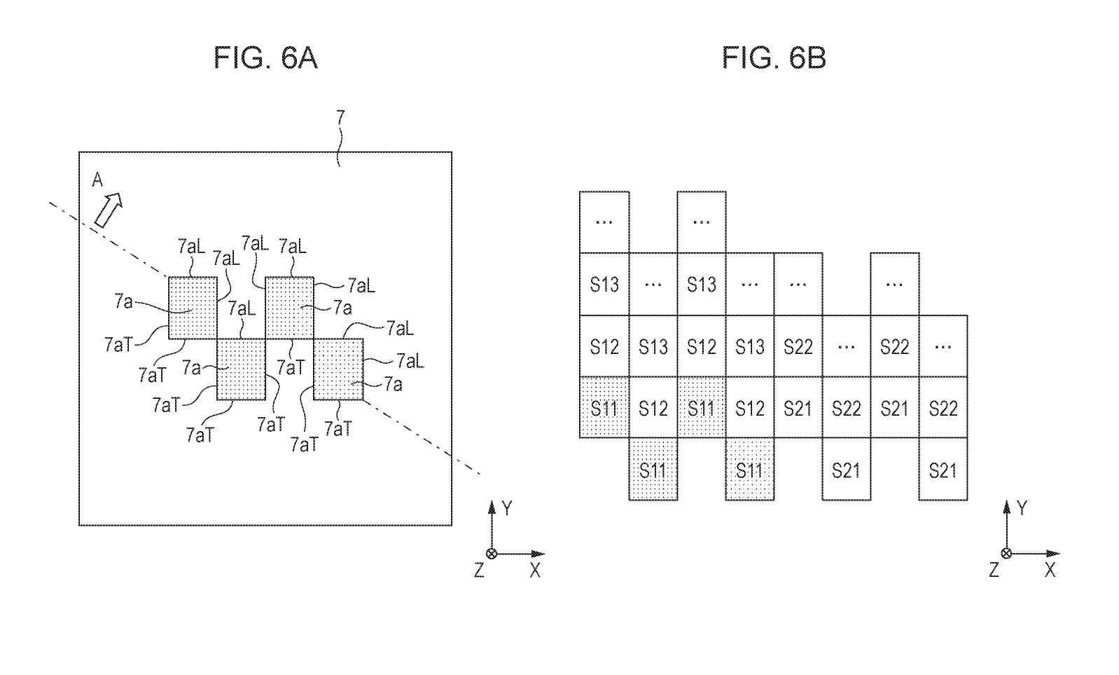

The mold 7 according to the first embodiment has a plurality of pattern regions 7a disposed along the diagonal lines of the pattern regions 7a. The pattern regions 7a of a mold 7 according to a second embodiment are disposed in a staggered pattern, as shown in FIG. 6A. Among the pattern regions 7a, the peripheral regions (edges) positioned in the forward direction with respect to the one-dot chain line in FIG. 6A (in the direction of arrow A in FIG. 6A) each have the leading edge 7aL, and the peripheral regions positioned in the backward direction each have the trailing edge 7aT. Since the peripheral regions of the individual pattern regions 7a are not shared, high-accuracy shape correction can be performed even if the shapes of the pattern regions 7a are non-continuous. By performing imprinting while moving the mold 7 one shot region by one shot region in the +Y direction in FIG. 6A, the trailing edge 7aT is imprinted on the first peripheral region 14L formed with the leading edge 7aL. In this way, a pattern is formed in the adjacent shot region so as to be superposed on an end of the pattern of the imprint material 14 formed in the shot region. Thus, the mold 7 has the leading edge 7aL (the first peripheral region) and the trailing edge 7aT (the second peripheral region) having different shapes at both ends of each pattern region 7a.

The sequence of forming patterns on the substrate 11 using the mold 7 shown in FIG. 6A will be described with reference to FIG. 6B. FIG. 6B illustrates the sequence of forming patterns on the shot regions on the substrate 11 using the mold 7 shown in FIG. 6A. First, patterns are formed on shot regions S11 in FIG. 6B by an imprinting process. Next, patterns are performed on shot regions S12 shifted by one shot region in the +Y direction (the imprinting step direction) by an imprinting process, and subsequent patterning is performed while the operation is shifted by one shot region in the +Y direction. Upon completion of imprinting in the +Y direction, the pattern regions 7a are shifted in the +X direction to perform imprinting on shot regions S21, S22, . . . . The mold 7 of the second embodiment forms patterns in shot regions S21 shifted by four shot regions in the direction (the +X direction) perpendicular to the imprinting step direction (the +Y direction).

Among the peripheral regions of the pattern regions 7a, the peripheral regions positioned in the forward direction with respect to the one-dot chain line in FIG. 6A (in the direction of arrow A in FIG. 6A) each have the leading edge 7aL, and the peripheral regions positioned in the backward direction each have the trailing edge 7aT.

The mold 7 shown in FIG. 6A is such that the plurality of pattern regions 7a are not arranged side by side (a plurality of pattern regions 7a are not disposed) in the imprinting step direction (the +Y direction). This allows the pattern regions 7a to be corrected in the Y direction using the above correction mechanism 18. Furthermore, combined use of a substrate heating mechanism for applying light (heat) to the substrate 11 to correct the shape of the shot regions of the substrate 11 (a substrate-shape correction mechanism) allows correction of the shape of non-continuous shot regions.

Forming patterns on the substrate 11 using the mold 7 according to the second embodiment allows a film of the imprint material 14 with a uniform thickness to be formed without forming a gap between the shot regions.

### Third Embodiment

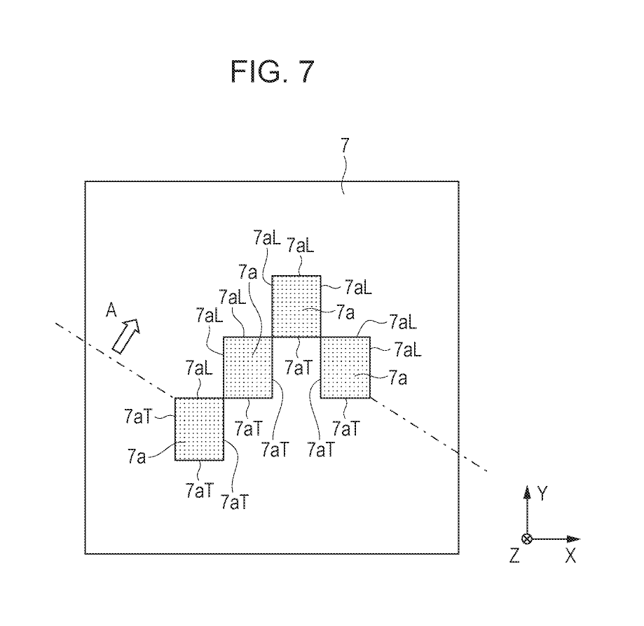

A mold 7 according to a third embodiment will be described with reference to FIG. 7. The arrangement of the pattern regions 7a of the mold 7 of the third embodiment is a combination of the diagonal disposition shown in FIGS. 5A and 5B and the staggered disposition shown in FIG. 6A. Also in this case, the pattern regions 7a are disposed so as not to be arranged side by side in one of the +X direction and the Y direction. Thus, by forming patterns while shifting the operation by one shot region in a direction in which the pattern regions 7a are not arranged side by side (the imprinting step direction), patterns can be formed without forming gaps.

For example, the pattern regions 7a in FIG. 7 are disposed so as not to be arranged side by side in the +Y direction. In this case, patterns are formed on the shot regions of the substrate 11 while the operation is shifted by one shot region in the +Y direction, and upon completion of imprinting in the +Y direction, the operation is shifted in the +X direction, and then the imprinting operation is repeated while the operation is shifted again by one shot region in the +Y direction. With the mold 7 of the third embodiment, patterns are formed in the shot regions of the substrate 11 by shifting the operation by four shot regions in a direction (the +X direction) perpendicular to the imprinting step direction (the +Y direction), and then shifting the operation by one shot region in the imprinting step direction.

Among the peripheral regions of the pattern regions 7a, the peripheral regions positioned in the forward direction with respect to the one-dot chain lines in FIG. 7 (in the direction of arrow A in FIG. 7) each have the leading edge 7aL, and the peripheral regions positioned in the backward direction each have the trailing edge 7aT. Thus, the mold 7 has the leading edge 7aL (the first peripheral region) and the trailing edge 7aT (the second peripheral region) having different shapes at both ends of each pattern region 7a.

Forming patterns on the substrate 11 using the mold 7 according to the third embodiment allows a film of an imprint material with a uniform thickness to be formed without forming a gap between the shot regions. Furthermore, the mold 7 shown in FIG. 7 is such that the plurality of pattern regions 7a are not arranged side by side (a plurality of pattern regions 7a are not disposed) in the imprinting step direction (the +Y direction). This allows the pattern regions 7a to be corrected in the Y direction using the above correction mechanism 18. Furthermore, combined use of a substrate heating mechanism for applying light (heat) to the substrate 11 to correct the shape of the shot regions of the substrate 11 (a substrate-shape correction mechanism) allows correction of the shape of non-continuous shot regions.

### Fourth Embodiment

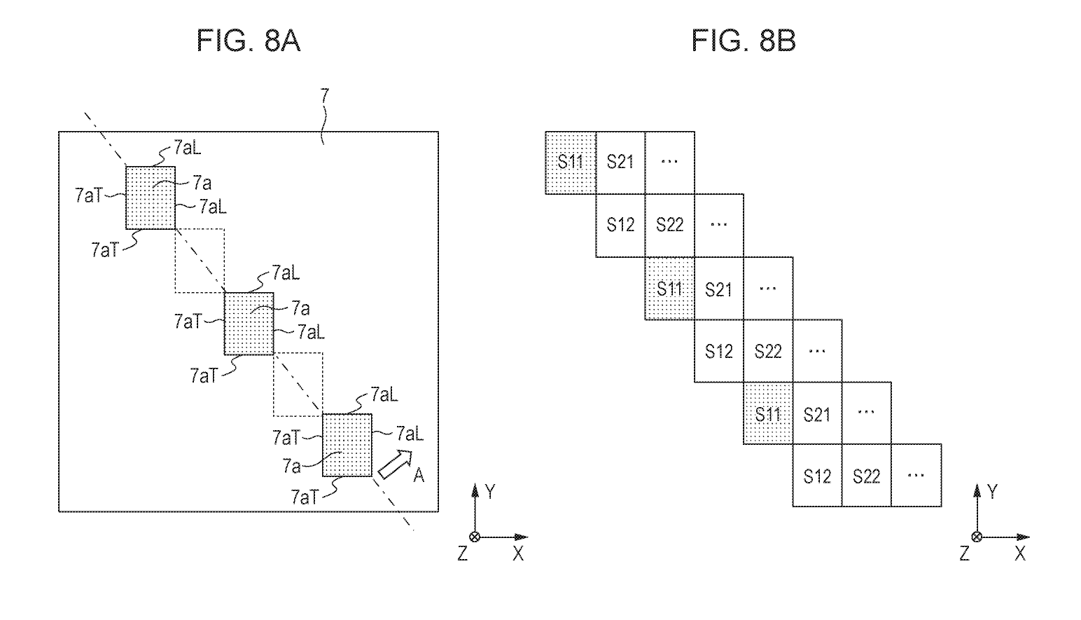

A mold 7 according to a fourth embodiment will be described with reference to FIGS. 8A and 8B. The pattern regions 7a described above are disposed such that their apices (the peripheral regions of the pattern regions 7) are shared by the apices of adjacent pattern regions 7a. The apices each continue to an adjacent pattern region 7a; however, the pattern regions 7a may be disposed away from each other from the viewpoint of the accuracy of superposing on the shot regions of the substrate 11.

FIG. 8A illustrates the arrangement of the pattern regions 7a of the mold 7 of the fourth embodiment. As shown in FIG. 8A, the plurality of pattern regions 7a are disposed, with a region (the dotted line region) having the same size as that of the pattern regions 7a away from each other along the diagonal line.

The sequence of forming patterns on the substrate 11 using the mold 7 shown in FIG. 8A will be described. First, patterns are formed in shot regions S11 in FIG. 8B by an imprinting process, and then patterns are formed in shot regions S12 so as to fill the spaces between the shot regions S11. Next, patterns are formed in shot regions S21 shifted by one shot region from the shot regions S11 in the +X direction (the imprinting step direction) by imprinting process. Also for the shot regions S12, patterns are formed in shot regions S22 shifted by one shot region in the +X direction.

Among the peripheral regions of the pattern regions 7a, the peripheral regions positioned in the forward direction with respect to the one-dot chain lines in FIG. 7 (in the direction of arrow A in FIG. 8A) each have the leading edge 7aL, and the peripheral regions positioned in the backward direction each have the trailing edge 7aT. In the case where the pattern regions 7a are disposed away from each other, the distance between the pattern regions 7a is an integral multiple of the sides of the pattern regions 7a to allow imprinting without gaps. To achieve imprinting without gaps, all of the pattern regions 7a are disposed at equal intervals. Thus, the mold 7 has the leading edge 7aL (the first peripheral region) and the trailing edge 7aT (the second peripheral region) having different shapes at both ends of each pattern region 7a.

Forming patterns on the substrate 11 using the mold 7 according to the fourth embodiment allows a film of the imprint material 14 with a uniform thickness to be formed without forming a gap between the shot regions. The mold 7 shown in FIG. 8A is such that the plurality of pattern regions 7a are not arranged side by side (a plurality of pattern regions 7a are not disposed) in the imprinting step direction (the +Y direction) and a direction perpendicular thereto (the +X direction). This allows the pattern regions 7a to be corrected in the Y direction and the X direction using the above correction mechanism 18. Furthermore, combined use of a substrate heating mechanism for applying light (heat) to the substrate 11 to correct the shape of the shot regions of the substrate 11 (a substrate-shape correction mechanism) allows correction of the shape of non-continuous shot regions. Method for Producing Product

A method for producing a device, or a product, (for example, a semiconductor integrated circuit element and a liquid-crystal display device) includes the process of forming a pattern on a substrate (for example, a wafer, a glass plate, and a film substrate) using the mold for imprinting, described above. The method of production can further include the process of etching the substrate on which the pattern is formed. In producing other products, such as patterned media (recording media) and optical elements, the method of production can include another process for processing the substrate on which the pattern is formed, instead of etching. The method of production of this embodiment is more advantageous than conventional methods in at least one of the performance, quality, production efficiency, and production cost of the product.

Having described embodiments of the present invention, it is to be understood that the present invention is not limited to the embodiments and can be variously modified and changed within the scope and spirit of the invention.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2015-109430, filed May 29, 2015, which is hereby incorporated by reference herein in its entirety.

What is claimed is:

1. A mold for use in an imprinting apparatus that forms patterns of an imprint material on a plurality of shot regions on a substrate, the mold comprising:
a plurality of pattern regions for forming the patterns, the pattern regions being disposed so as not to be next to each other in a first direction and a second direction,
wherein the plurality of pattern regions each have a first peripheral region and a second peripheral region at both ends in the first direction, the first peripheral region and the second peripheral region being disposed such that, in forming the patterns in the plurality of shot regions along the first direction, a pattern of the imprint material formed in a shot region using the first peripheral region of the pattern region is superposed on a pattern of the imprint material formed in a next shot region using the second peripheral region.

2. The mold according to claim 1,
wherein, in bringing the mold into contact with the imprint material on the substrate, the first peripheral region and the second peripheral region have different structures such that distance between the first peripheral region and the substrate is shorter than distance between the second peripheral region and the substrate.

3. The mold according to claim 1,
wherein, in bringing the imprint material on the substrate into contact with the mold and curing the imprint material, distance between the second peripheral region and the substrate is longer than distance between a surface of a protrusion of a relief pattern at a center of the pattern region and a surface of the substrate.

4. The mold according to claim 1,
wherein, in bringing the imprint material on the substrate into contact with the mold and curing the imprint material, distance between a surface of the first peripheral region and the substrate is shorter than distance between a surface of a protrusion of a relief pattern at a center of the pattern region and a surface of the substrate.

5. The mold according to claim 1,
wherein the plurality of pattern regions have a rectangular shape,
wherein the first direction is a direction along one side of the pattern regions, and
wherein the plurality of pattern regions are disposed along a diagonal line of the rectangular shape.

6. The mold according to claim 1, wherein the first peripheral region and the second peripheral region are disposed at both ends of each of the pattern regions in the second direction.

7. A mold for use in an imprinting apparatus that forms patterns of an imprint material on a plurality of shot regions on a substrate, the mold comprising:
a plurality of pattern regions for forming the patterns, the pattern regions being disposed not to be next to each other in a first direction and a second direction; and
wherein the plurality of pattern regions each have a first peripheral region and a second peripheral region at both ends in the first direction, the first peripheral region and the second peripheral region being disposed with the pattern region between the first peripheral region and the second peripheral region in the first direction, and
wherein the mold in the first peripheral region is higher than the mold in the second peripheral region.

8. A method of imprinting for forming patterns in a plurality of shot regions along a first direction by repeating an imprinting process on an imprint material on a substrate using a mold, the method comprising:
during the imprinting process, forming patterns in a plurality of shot regions disposed so as not to be next to each other in a second direction,
wherein, in forming patterns in shot regions adjacent in the first direction, the patterns are formed in the adjacent shot regions such that an end of a pattern of the imprint material in an adjacent shot region is superposed on an end of a pattern of the imprint material formed in a preceding shot region on the substrate.

9. A method of imprinting for forming a pattern of an imprint material in a shot region on a substrate using the mold according to claim 1, the method comprising steps of:
bringing the imprint material on the substrate and the mold into contact with each other; and
curing the imprint material on the substrate,
wherein, in the step of bringing the imprint material and the mold into contact with each other, patterns are formed on the shot regions adjacent in the first direction such that an end of a pattern of the imprint material on the substrate formed using the second peripheral region is superposed on an and of a pattern of the imprint material on the substrate formed using the first peripheral region.

10. An imprinting apparatus for forming a pattern of an imprint material on a substrate using the mold according to claim 1, the apparatus comprising:
a holding unit configured to hold the mold; and
a deforming mechanism configured to change the mold in shape by applying force in at least one of the first direction and the second direction.

11. A method for producing a product, comprising the steps of:
forming a pattern of an imprint material on a substrate using the imprinting apparatus according to claim 10; and
processing the substrate on which the pattern is formed in the forming step.
